(19) United States
(12) Patent Application Publication
(10) Pub. No.: US 2006/0191567 A1
(43) Pub. Date: Aug. 31, 2006

(54) Photoelectric conversion element and method for producing photoelectric conversion element

(75) Inventor: Tetsuro Mitsui, Minami-Ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/362,851

(22) Filed: Feb. 28, 2006

(30) Foreign Application Priority Data
Feb. 28, 2005 (JP) P. 2005-053006

(51) Int. Cl. H01L 31/00

(52) U.S. Cl. 136/256

(57) ABSTRACT

A photoelectric conversion element comprising: a substrate; a conductive layer; a photoelectric conversion layer; and a transparent conductive layer, provided in this order, wherein the transparent conductive layer has a sheet resistance of from 100 to 10000Ω/□.

### FIELD OF THE INVENTION

This invention relates to a photoelectric conversion element having a transparent electrode on a photoelectric conversion layer.

### BACKGROUND OF THE INVENTION

In a photoelectric conversion element having a transparent electrode formed on a photoelectric conversion part, it has been regarded as favorable to achieve a higher transmittance of the transparent electrode and a lower resistance thereof so as to increase the absolute quantity of light falling into the photoelectric conversion part and increase the carrier reading efficiency after the photoelectric conversion, As the materials for forming the transparent electrode, transparent conductive oxide layer such as ITO is preferably used as a material having both of a high transmittance and a low resistance. However, it has been a technical problem to establish both of a high transmittance and a low resistance in the formation of a transparent electrode. In general, the resistance is liable to increase with an increase in the transmittance. To establish a low resistance, on the other hand, it is frequently observed that the material and forming method of the layer are highly restricted, for example, there arises the need for the crystallization of the layer material.

### SUMMARY OF THE INVENTION

It is intended to improve the sensitivity and reduce noises of a photoelectric conversion element and provide a method of more conveniently forming a transparent electrode to be used therein.

(1) A photoelectric conversion element comprising a conductive layer, a photoelectric conversion layer and a transparent conductive layer stacked in this order on a substrate, wherein the sheet resistance of the transparent conductive layer is 100Ω/□ or more but not more than 10000 Ω/□.

(2) A photoelectric conversion element as described in the above (1) wherein the sheet resistance is 100Ω/□ or more but not more than 3000Ω/□.

(3) A photoelectric conversion element as described in the above (1) or (2) wherein the sheet resistance is 500Ω/□ or more but not more than 3000Ω/□.

(4) A photoelectric conversion element as described in any one of the above (1) to (3) wherein the sheet resistance is 500Ω/□ or more but not more than 1000Ω/□.

(5) A photoelectric conversion element as described in any one of the above (1) to (4) wherein the transmittance in the incidence wavelength region of 400 nm or longer but not longer than 700 nm is 85% or more.

(6) A method for producing a photoelectric conversion element as described in any one of the above (1) to (5) wherein the transparent conductive layer is formed by a plasma-free layer-formation method.

According to the invention, it is possible to increase the sensitivity of a photoelectric conversion element and lower the noises thereof and, moreover, more conveniently fabricate the photoelectric conversion element.

### BRIEF DESCRIPTION OF THE DRAWINGS

FIG. 1 is a sectional schematic drawing which shows a preferred embodiment of the photoelectric conversion element according to the invention.

### DESCRIPTION OF THE REFERENCE NUMERALS AND SIGNS

101 antireflective layer
102 infrared-cutting dielectric multiple layer
103, 104 protective layer
105 transparent counter electrode
106 buffer layer
107 electron blocking layer
108 p layer
109 n layer
110 hole blocking layer
111, 112 layer containing metal wiring
113 monocrystalline silicone base
114 transparent pixel electrode
15 plug
116 pad
117 photo blocking layer
118 connection electrode
119 metal wiring
120 counter electrode pad
121 n layer
122 p layer
123 n layer
124 p layer
125 n layer
126 transistor
127 signal-reading pad

### DETAILED DESCRIPTION OF THE INVENTION

The characteristic of the photoelectric conversion element of the invention resides in that, in a photoelectric conversion element comprising a conductive layer, a photoelectric conversion layer and a transparent conductive layer which are stacked on a substrate in this order, the sheet resistance of the transparent conductive layer is 100Ω/□ or more but not more than 10000Ω/□, preferably 100Ω/□ or more but not more than 3000Ω/□, more preferably 500Ω/□ or more but not more than 3000Ω/□ and especially preferably 500Ω/□ or more but not more than 1000Ω/□.

It has been considered that a transparent conductive layer has a lower resistance than a transparent electrode to be used as a solid-state image pickup element. However, we have surprisingly found out that a higher resistance is preferred within a specific range in the case of considering dark current noises. That is to say, the sheet resistance of the transparent conductive layer is 100Ω/□ or more but not more than 10000Ω/□, preferably 100Ω/□ or more but not more than 3000Ω/□, more preferably 500Ω/□ or more but not more than 3000Ω/□ and especially preferably 500Ω/□ or more but not more than 1000Ω/□.

In the case where such a high sheet resistance can be established, in particular, in the case of using a transparent conductive layer made of an oxide as the transparent conductive layer, the restriction during the layer formation can be relieved.

Concerning charge transfer, a higher electrode mobility is preferred for increasing the response speed. From the viewpoint of noises, however, a lower carrier density is preferred. Accordingly, a transparent conductive layer having a low carrier density and a high mobility is preferable. The carrier density may be reduced by, for example, lessening stoichiometric mismatch in the case of a transparent conductive oxide layer. By lessening the stoichiometric mismatch, a high transmittance can be obtained and, moreover, the charge mobility can be increased since defects in crystals can be lessened thereby. This can be achieved by, in the course of the layer formation, introducing oxygen in a larger amount than the oxygen inlet level at which the sheet resistance is minimized.

To increase the electrode mobility in a transparent conductive oxide layer, it has been a common practice to employ a technique whereby the layer can be formed while lessening defects in crystals, i.e., lessening stoichiometric mismatch (for example, introducing oxygen in the course of the layer formation to thereby lessen oxygen defects in the layer) as discussed above. To increase the carrier density, on the contrary, use is made of a technique of causing stoichiometric mismatch (for example, reducing the oxygen inlet amount during the layer formation to cause oxygen defects in the layer, thereby introducing carrier). Although a high mobility and a high carrier density are required to obtain a layer having a lower resistance, means of increasing the mobility (i.e., means of minimizing defects in crystals) is contradictory to means of increasing the carrier density. Accordingly, the sheet resistance is increased in both of the cases where the oxygen inlet amount is larger than the oxygen inlet level at which the sheet resistance is minimized and where it is smaller than the level.

From the viewpoint different from the mobility or carrier density of the transparent conductive layer (for example, in aiming at preventing damages with the use of an organic layer as a photoelectric conversion layer), it is favorable to introduce less or even no oxygen during the layer formation. This can be established by introducing oxygen in a smaller amount than the oxygen inlet level at which the sheet resistance is minimized so as to give a sheet resistance falling within the range as defined in the invention.

Within the range of sheet resistance as defined herein, the thickness of the transparent conductive layer of the invention preferably ranges from 5 to 100 nm, still preferably from 5 to 50 nm and particularly preferably from 5 to 30 nm.

To employ in a solid-state image pickup element having a stacked structure wherein a photoelectric conversion site is further provided below a photoelectric conversion part sandwiched between a conductive layer and a transparent conductive layer, it is preferable that the conductive layer of the invention is transparent because light should penetrate into the lower layer. To increase the amount of light attaining the photoelectric conversion layer and increase the sensitivity, it is also preferable that the transparent conductive layer has a high transmittance. In the case of employing in an image sensor and so on, the transmittance of visible light having a wavelength of 400 nm or longer but not longer than 700 nm is preferably 85% or more, still preferably 90% or more.

In the case where an organic layer is used as the photoelectric conversion layer and the transparent conductive layer is formed by a commonly employed method such as the sputtering method, it is sometimes observed that the performance of the photoelectric conversion layer is worsened due to the damage by plasma. Therefore, it is preferred that the transparent conductive layer is formed by a plasma-free method. The term “plasma-free” as used herein means a state wherein no plasma generates in the course of forming the transparent conductive layer or the distance between a plasma source and a substrate is 2 cm or longer, preferably 10 cm or longer and still preferably 20 cm or longer and, therefore, plasma is lessened until it reaches the substrate.

As examples of a device wherein no plasma generates during the layer-formation of a transparent electrode layer (a transparent conductive layer), an electron beam deposition device (an EB deposition device) and a pulse laser deposition device may be cited. Namely, use can be made of an EB deposition device or a pulse laser deposition device reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto. A method of forming a transparent electrode layer by using an EB deposition device will be called the EB deposition method while a method of forming a transparent electrode layer with the use of a pulse laser deposition device will be called the pulse laser deposition method hereinafter.

As examples of a device having a distance between a plasma source and a substrate of 2 cm or longer and, therefore, plasma is lessened until it reaches the substrate (hereinafter referred to as a plasma-free layer forming device), a counter target sputtering device and an arc plasma deposition device may be cited. Namely, use can be made of devices reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto.

Considering an element having a great number of pixels and a high resolution, it is preferable that the conductive layer of the invention is pixelated.

The transparent conductive layer having a sheet resistance of from 100 to 10000Ω/□ used in the invention can be constructed by selecting an appropriate material and an appropriate layer-forming method and controlling the same. In the case of ITO, for example, the crystallinity and the chemical composition can be altered by controlling the layer-forming temperature, the addition level of oxygen and so on in the step of using the sputtering method and thus the sheet resistance can be controlled.

In forming a layer with the use of, e.g., ITO, the addition level of oxygen is usually determined so that the resistance attains the minimum and stable level in the course of the sputtering layer-formation. In contrast, a layer suitable for the transparent conductive layer of the invention having a sheet resistance of from 100 to 10000Ω/□ can be obtained by, for example, performing the layer formation while employing oxygen in an extremely smaller amount (for example, no oxygen, or ½ or less amount of oxygen is introduced) or in an extremely larger amount (for example, twice or more amount of oxygen is introduced) and appropriately reducing the layer thickness.

In forming the transparent conductive layer, the substrate temperature is preferably 500° C. or lower, still preferably 300° C. or lower, still preferably 200° C. or lower and still preferably 150° C. or lower.

Examples of the material for making the transparent conductive layer satisfying the requirements in the invention (a sheet resistance being from 100 to 10000Ω/□) include electrically conductive metal oxides such as tin oxide, zinc oxide, indium oxide and indium tin oxide (ITO), metals such as gold, silver, chromium and nickel, mixtures or stacks of these metals with electrically conductive metal oxides, inorganic conductive materials such as copper iodide and copper sulfide, organic conductive materials such as polyaniline, polythiophene and polypyrrole, silicone compounds and stacks thereof with ITO. Electrically conductive metal oxides are preferable and In₂O₃-based materials and ZnO-baaed materials are still preferable. In particular, ITO and IZO are preferable from the viewpoints of productivity, high conductivity, transparency and so on.

(Photoelectric Conversion Element)

Next, the photoelectric conversion element of the invention will be illustrated.

The photoelectric conversion element of the invention comprises an electromagnetic wave absorption/photoelectric conversion part (comprising a conductive layer, a photoelectric conversion layer and a transparent conductive layer) and a charge storage/transfer/reading part for the charge generated by the photoelectric conversion.

The electromagnetic wave absorption/photoelectric conversion part in the invention has a stacked structure composed of at least two layers whereby at least blue light, green light and red light can be absorbed and photoelectrically converted. The blue light absorption layer (B) can absorb light with wavelength of 400 nm or longer but not longer than 500 nm and the absorption index of the peak wavelength in this region is preferably 50% or more. The green light absorption layer (G) can absorb light with wavelength of 500 nm or longer but not longer than 600 nm and the absorption index of the peak wavelength in this region is preferably 50% or more. The red light absorption layer (R) can absorb light with wavelength of 600 nm or longer but not longer than 700 nm and the absorption index of the peak wavelength in this region is preferably 50% or more. These layers may be formed in any order. In a stacked structure composed of three layers, use may be made of the orders of, from the upper side (incident light side), BGR, BRG, GBR, GRB, RBG and RGB. It is preferable that G is provided as the uppermost layer. In a stacked structure composed of two layers wherein an R layer is provided as the upper layer, BG layers are provided on a single plane to form the lower layer. In the case where a B layer is provided as the upper layer, GR layers are provided on a single plane to form the lower layer. In the case where a G layer is provided as the upper layer, BR layers are provided on a single plane to form the lower layer. It is preferable that the G layer is provided as the upper layer while the BR layers are provided as the lower layer. In such a case where two light absorption layers are provided on a single plane as the lower layer, it is preferable to form a filter layer (for example, in a mosaic structure) for color separation on the upper layer or between the upper and lower layers. It is also possible in some cases to form additional layer(s) as the fourth layer or higher or on the same plane.

In the invention, the charge storage/transfer/reading part is provided under the electromagnetic wave absorption/photoelectric conversion part. It is preferred that the electromagnetic wave absorption/photoelectric conversion part in the lower layer also serves as the charge storage/transfer/reading part.

In the invention, the electromagnetic wave absorption/photoelectric conversion part comprises an organic layer, an inorganic layer or a mixture of an organic layer with an inorganic layer. Organic layers may be B/G/R layers Alternatively, inorganic layers may be B/G/R layers. A mixture of an organic layer with an inorganic layer is preferred. Fundamentally, one or two inorganic layers are formed in the case of forming an organic layer, and one inorganic layer is formed in the case of forming two organic layers. In the case of forming an organic layer and an inorganic layer, the inorganic layer forms electromagnetic wave absorption/photoelectric conversion parts in two or more colors on a single plane. It is preferable that the upper layer is an organic layer serving as the G layer while the lower layers are inorganic layers comprising the B layer and the R layer in this order from the upper side. It is also possible in some cases to form additional layer(s) as the fourth layer or higher or on the same plane. In the case where organic layers are B/C/R layers, the charge storage/transfer/reading part is formed under these layers. In the case of using an inorganic layer as the electromagnetic wave absorption/photoelectric conversion part, the inorganic layer also serves as the charge storage/transfer/reading part.

(Organic Layer)

Now, the organic layer in the invention will be illustrated. In the invention, an electromagnetic wave absorption/photoelectric conversion part made of an organic layer comprises the organic layer located between a pair of electrodes. The organic layer is made up of an electromagnetic wave absorption part, an electron transportation part, a photoelectric conversion part, a hole transportation part, an electron blocking part, a hole blocking part, a crystallization prevention part, electrodes, an interlayer contact improvement part and so on which are piled up or mixed together. It is preferable that the organic layer contains an organic p-type compound or an organic n-type compound. The organic p-type semiconductor (compound), which is a donor type organic semiconductor (compound), is typified mainly by a hole-transporting organic compound, i.e., an organic compound being liable to donate electron. To speak in greater detail, it means an organic compound having a lower ionization potential in the case of using two organic materials in contact with each other. That is to say, any compound capable of donating electron can be used as the donor type organic compound. For example, use can be made of triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonole compounds, polyamine compounds, indole compounds, pyrrole compounds, pyrazole compounds, polyarylene compounds, fused ring aromatic carbon ring compounds (naphthalene derivatives, anthracene derivatives, phenanthrene derivatives, tetracene derivatives, pyrene derivatives, perylene derivatives and fluoranthene derivatives), metal complexes having nitrogen-containing heterocyclic compounds as a ligand and so on. However, the invention is not restricted to these compounds and use may be made, as the donor type organic semiconductor, of any organic compound which has a lower ionization potential than the organic compound employed as the n-type (acceptor type) compound as discussed above.

The organic n-type semiconductor (compound), which is an acceptor type organic semiconductor (compound), is typified mainly by an electron-transporting compound, i.e., an organic compound being liable to accept electron. To speak in greater detail, it means an organic compound having a higher affinity in the case of using two organic materials in contact with each other. That is to say, any compound capable of accepting electron can be used as the acceptor type organic compound. For example, use can be made of fused ring aromatic carbon ring compounds (naphthalene derivatives, anthracene derivatives, phenanthrene derivatives, tetracene derivatives, pyrene derivatives, perylene derivatives and fluoranthene derivatives), 5- to 7-membered heterocyclic compounds having a nitrogen atom, an oxygen atom or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrralizine, pyrrolopyridine, thiadiazolopyridine, dibenzazepine and tribenzazepine), polyarylene compounds, fluorene compounds, cyclopentadiene compounds, silyl compounds, metal complexes having nitrogen-containing heterocyclic compounds as a ligand and so on. However, the invention is not restricted to these compounds and use may be made, as the acceptor type organic semiconductor, of any organic compound which has a higher affinity than the organic compound employed as the donor type organic compound as discussed above.

Although any compounds are usable as the p-type organic dye or the n-type organic dye, preferable examples thereof include cyanine dyes, styryl dyes, hemicyanine dyes, merocyanine dyes (including zeromethine merocyanine (simple merocyanine)), three-nuclear merocyanine dyes, four-nuclear merocyanine dyes, rhodacyanine dyes, complex cyanine dyes, complex merocyanine dyes, aro polar dyes, oxonole dyes, hemioxonole dyes, squarium dyes, croconium dyes, azamethine dyes, coumarine dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, fused ring aromatic carbon ring compounds (naphthalene derivatives, anthracene derivatives, phenanthrene derivatives, tetracene derivatives, pyrene derivatives, perylene derivatives and fluoranthene derivatives) and so on.

Next, a metal complex compound will be illustrated. A metal complex compound is a metal complex which carries a ligand having at least one nitrogen atom, oxygen atom or sulfur atom and coordinating with a metal. Although the metal ion in such a metal complex is not particularly restricted, preferable examples thereof include beryllium ion, magnesium ion, aluminum ion, gallium ion, zinc ion, indium ion and tin ion, still preferably beryllium ion, aluminum ion, gallium ion or zinc ion, and still preferably aluminum ion or zinc ion, As the ligand contained in the above metal complex, various publicly known ligands may be cited. For example, use can be made of ligands reported in Photochemistry and Photophysics of Coordination Compounds, published by Springer-Verlag, H. Yersin (1987) and Yuki Kinzoku Kagaku-Kiso to Oyo, published by Shokabo, Akio Yamamoto (1982) and so on.

Preferable examples of the above ligand include nitrogen-containing heterocyclic ligands (preferably having from 1 to 30 carbon atoms, still preferably from 2 to 20 carbon atoms, and particularly preferably form 3 to 15 carbon atoms; including both of monodentate ligands and higher, bidentate ligands being preferred, e.g., pyridine ligands, bipyridyl ligands, quinolynol ligands, hydroxyphenylazole ligands such as hydroxyphenylbenzimidazole ligand, hydroxyphenylbenzoxazole ligand and hydroxyphenylimidazole ligand), alkoxy ligands (preferably having from 1 to 30 carbon atoms, still preferably from 1 to 20 carbon atoms and particularly preferably from 1 to 10 carbon atoms, such as methoxy, ethoxy, butoxy and 2-ethylhyxyloxy), aryloxy ligands (preferably having from 6 to 30 carbon atoms, still preferably from 6 to 20 carbon atoms and particularly preferably from 6 to 12 carbon atoms, such as phenyloxy, 1-naphthyloxy, 2-naphthyloxy, 2,4,6-trimethylphenyloxy and 4-biphenyloxy), heteroaryloxy ligands (preferably having from 1 to 30 carbon atoms, still preferably form 1 to 20 carbon atoms and particularly preferably from 1 to 12 carbon atoms, such as pyridyloxy, pyrazyloxy, pyrimidyloxy and quinolyloxy), alkylthio ligands (preferably having from 1 to 30 carbon atoms, still preferably from 1 to 20 carbon atoms and particularly preferably from 1 to 12 carbon atoms, such as methylthio and ethylthio), arylthio ligands (preferably having from 6 to 30 carbon atoms, still preferably from 6 to 20 carbon atoms and particularly preferably from 6 to 12 carbon atoms, such as phenylthio), heterocycle-substituted thio ligands (preferably having from 1 to 30 carbon atoms, still preferably from 1 to 20 carbon atoms and particularly preferably from 1 to 12 carbon atoms, such as pyridylthio, 2-benzimidazolylthio, 2-benzoxazolylthio and 2-benzthiazolylthio) and siloxy ligands (preferably having from 1 to 30 carbon atoms, still preferably from 3 to 25 carbon atoms and particularly preferably from 6 to 20 carbon atoms, such as triphenylsiloxy group, triethoxysiloxy group and triisopropylsiloxy group). Still preferable examples thereof include nitrogen-containing heterocyclic ligands, aryloxy ligands, heteroaryloxy groups and siloxy ligands, and nitrogen-containing heterocyclic ligands, aryloxy ligands and siloxy ligands are still preferable.

In the invention, it is preferable to contain a photoelectric conversion layer (a photosensitive layer) which has a p-type semiconductor layer and an n-type semiconductor layer between a pair of electrodes and also has a bulk heterojunction layer containing the p-type semiconductor and the n-type semiconductor as an intermediate layer between these semiconductor layers. In this case, the shortage of the organic layer of having a short carrier diffusion length can be overcome owing to the bulk heterojunction structure in the organic layer and thus the photoelectric conversion efficiency can be increased. The bulk heterojunction structure is described in detail in Japanese Patent Application No. 2004-080639.

It is preferable in the invention to contain a photoelectric conversion layer (a photosensitive layer which has two or more repeating structure units of a pn junction layer comprising a p-type semiconductor layer and an n-type semiconductor layer between a pair of electrodes (a tandem structure). It is still preferable to insert a thin layer made of an electrically conductive material between these repeating structure units. Although the number of the repeating structure units of the pn junction layers (the tandem structure) is not restricted, it preferably ranges from 2 to 50, still preferably from 2 to 30 and particularly preferably 2 or 10, from the viewpoint of achieving a high photoelectric conversion efficiency. As the electrically conductive material, silver or gold is preferable and silver is most desirable. The tandem structure is described in detail in Japanese Patent Application No. 2004-079930.

In a photoelectric conversion layer having a p-type semiconductor layer and an n-type semiconductor layer between a pair of electrodes (preferably a mixture/dispersion (bulk heterojunction) layer), a photoelectric conversion layer containing an organic compound having controlled orientation at least in one of the p-type semiconductor and the n-type semiconductor is preferable and a photoelectric conversion layer containing organic compounds having (possibly) controlled orientation in both of the p-type semiconductor and the n-type semiconductor is still preferred. As the organic compound to be used in the organic layer of the photoelectric conversion layer, it is preferable to employ one having a π-conjugated electron. It is favorable to use a compound having been oriented to give an angle of this π electron plane which is not perpendicular but as close to parallel as possible to the substrate (the electrode substrate). The angle to the substrate is preferably 0° or larger but not larger than 80°, still preferably 0° or larger but not larger than 60°, still preferably 0° or larger but not larger than 40°, still preferably 0° or larger but not larger than 20°, particularly preferably 0° or larger but not larger than 10° and most desirably 0° (i.e., being parallel to the substrate). The organic layer comprising the organic compound with controlled orientation as described above may be at least a part of the whole organic layer. It is preferable that the part with controlled orientation amounts to 10% or more based on the whole organic layer, still preferably 30% or more, still preferably 50% or more, still preferably 70% or more, particularly preferably 90% or more and most desirably 100%. In this construction, the shortage of the organic layer of having a short carrier diffusion length can be overcome by controlling the orientation of the organic compound in the organic layer and thus the photoelectric conversion efficiency can be increased.

In the where the organic compound has controlled orientation, it is still preferable that the heterojunction plane (for example, a pn junction plane) is not parallel to the substrate. It is favorable that the organic compound is oriented so that the heterojunction plane is not parallel to the substrate (the electrode substrate) but as close to perpendicular as possible thereto. The angle to the substrate is preferably 10° or larger but not larger than 90°, still preferably 30° or larger but not larger than 90°, still preferably 50° or larger but not larger than 90°, still preferably 70° or larger but not larger than 90°, particularly preferably 80° or larger but not larger than 90° and most desirably 90° (i.e., being perpendicular to the substrate). The layer of the compound with controlled heterojunction plane as described above may be a part of the whole organic layer. The part with controlled orientation preferably amounts to 10% or more based on the whole organic layer, still preferably 30% or more, still preferably 50% or more, still preferably 70% or more, particularly preferably 90% or more and most desirably 100%. In such a case, the area of the heterojunction plane in the organic layer is enlarged and, in its turn, electrons, holes, electron-hole pairs, etc. formed in the interface can be carried in an increased amount, which makes it possible to improve the photoelectric conversion efficiency. The photoelectric conversion layer (a photosensitive layer) in which the orientation is controlled in both of the heterojunction plane and the π-electron plane as described above, the photoelectric conversion efficiency can be particularly improved. These states are described in detail in Japanese Patent Application No. 2004-079931.

From the viewpoint of light absorption, a larger thickness of an organic dye layer is preferred. By taking the percentage not contributing to charge separation into consideration, however, the thickness of the organic dye layer according to the invention is preferably 30 nm or more but not more than 300 nm, still preferably 50 nm or more but not more than 250 nm, and particularly preferably 80 nm or more but not more than 200 nm.

[Method of Forming Organic Layer]

The layers containing these organic compounds can be formed by a dry layer-forming method or a wet layer-forming method. Specific examples of the dry layer-forming method include physical vapor phase epitaxy methods such as the vacuum vapor deposition method, the sputtering method, the ion plating method and the MBE method, and CVD methods such as the plasma polymerization method. Examples of the wet layer-forming method include the casting method, the spin coating method, the dipping method and the LB method.

In the case of using a polymer compound as at least one of the p-type semiconductor (compound) and the n-type semiconductor (compound), it is favorable to form the layer by a wet layer-forming method which can be easily carried out. When a dry layer-forming method such as the vapor deposition method is employed, it is highly difficult to employ a polymer compound because of a fear of decomposition. In such a case, use may be preferably made of a corresponding oligomer as a substitute for the polymer. In the case of using a low-molecular weight compound in the invention, use is preferably made of a dry layer-forming method and the vacuum vapor deposition method is particularly preferred. Fundamental parameters in the vacuum vapor deposition method include a method of heating a compound (e.g., the resistance heating method, the electron beam heating/deposition method or the like), the shape of the deposition source such as a crucible or a boat, the degree of vacuum, the deposition temperature, the substrate temperature, the deposition speed and so on. To achieve uniform deposition, it is favorable to carry out the deposition while rotating the substrate. A higher degree of vacuum is preferred. The vacuum vapor deposition is performed at a degree of vacuum of 10⁻⁴ Torr (1.33×10⁻² Pa) or lower, preferably 10⁻⁶ Torr (1.33×10⁻⁴ Pa) or lower and particularly preferably 10⁻⁸ Torr (1.33×10⁻⁶ Pa) or lower. It is preferable to carry out all of the vapor deposition steps in vacuo. Fundamentally, the subject compound should be prevented from direct contact with the external oxygen or moisture. The vacuum vapor deposition conditions as described above should be strictly controlled, since the crystalinity, amorphous properties, density and denseness of the organic layer are affected thereby. It is preferable to PI or PID control the deposition speed with the use of a layer thickness monitor such as a crystal oscillator or an interferometer. In the case of depositing two or more compounds at the same time, use may be preferably made of the co-deposition method, the flash deposition method or the like.

(Electrode)

The electromagnetic wave absorption/photoelectric conversion part comprising organic layers according to the invention is located between a pair of electrodes and the pair of electrodes respectively serve as a pixel electrode and a counter electrode. It is preferable that the lower layer serves as the pixel electrode.

It is preferable that the counter electrode takes out holes from a hole-transporting photoelectric conversion layer or a hole-transporting layer. As a material for making the counter electrode when it is not included in the scope of the transparent conductive layer of the invention having a sheet resistance of from 100 to 10000Ω/□, use may be made of a metal, an alloy, a metal oxide, an electrically conductive compound or a mixture thereof. It is preferable that the pixel electrode (including the conductive layer of the invention) can take out electrons from an electron-transporting photoelectric conversion layer or an electron-transporting layer. It is selected by considering the adhesiveness to the adjacent layers such as the electron-transporting photoelectric conversion layer and the electron-transporting layer, electron affinity, ionization potential, stability and so on. Specific examples thereof include electrically conductive metal oxides such as tin oxide, zinc oxide, indium oxide and indium tin oxide (ITO), metals such as gold, silver, chromium and nickel, mixtures or stacks of these metals with electrically conductive metal oxides, inorganic conductive materials such as copper iodide and copper sulfide, organic conductive materials such as polyaniline, polythiophene and polypyrrole, silicone compounds and stacks thereof with ITO. Electrically conductive metal oxides are preferable and ITO and IZO are still preferable from the viewpoints of productivity, high conductivity, transparency and so on. The layer thickness may be appropriately selected depending on material. In usual, the thickness of the pixel electrode is preferably 10 nm or more but not more than 1 μm, still preferably 30 nm or more but not more than 500 nm and still preferably 50 nm or more but not more than 300 nm.

The pixel electrode and the counter electrode, when it is not included in the scope of the transparent conductive layer of the invention having a sheet resistance of from 100 to 10000 Ω/□, may be constructed by various methods depending on materials. In the case of using ITO, for example, a layer may be formed by the electron beam method, the sputtering method, the resistance heat deposition method, the chemical reaction method (sol-gel method, etc.) or the method of coating with an indium tin oxide dispersion. In the case of using ITO, it is also possible to perform the UV-ozone treatment, the plasma treatment or the like.

It is preferable to construct a transparent electrode layer, when it is not included in the scope of the transparent conductive layer of the invention having a sheet resistance of from 100 to 10000Ω/□, under plasma-free conditions. By constructing the transparent electrode layer under plasma-free conditions, effects of plasma on the substrate can be minimized and thus favorable photoelectric conversion characteristics can be established. The term “plasma-free” as used herein means a state wherein no plasma generates in the course of forming a transparent electrode layer or the distance between a plasma source and a substrate is 2 cm or longer, preferably 10 cm or longer and still preferably 20 cm or longer and, therefore, plasma is lessened until it reaches the substrate.

As a device wherein no plasma generates during the layer-formation of a transparent electrode layer, use can be made of those as cited above.

Now, the electrodes in the electromagnetic wave absorption/photoelectric conversion part of the invention will be illustrated in greater detail. The photoelectric conversion layer in the organic layer, which is located between a pixel electrode layer and a counter electrode layer, may comprises an interelectrode material or the like. The term “pixel electrode layer” means an electrode layer constructed in the upper part of the substrate on which a charge storage/transfer/reading part is formed. It is usually divided for individual pixels so that a signal charge converted by the photoelectric conversion layer can be read for each pixel on the charge storage/transfer/signal reading circuit substrate to give an image.

The term “counter electrode layer” means an electrode layer having a function of sandwiching the photoelectric conversion layer together with the pixel electrode layer to thereby emit a signal charge having a polarity opposite to the signal charge. Since it is unnecessary to divide the emission of the signal charge for individual pixels, pixels usually have a counter electrode layer in common. Thus, it is sometimes called a common electrode layer.

The photoelectric conversion layer is located between the pixel electrode layer and the counter electrode layer. The photoelectric conversion function is established by the photoelectric conversion layer, the pixel electrode layer and the counter electrode layer.

In the case where a single organic layer is provided on a substrate, the photoelectric conversion layer stack is composed of, for example, a substrate and a pixel electrode layer (being a transparent electrode layer in many case, corresponding to the conductive layer of the invention), a photoelectric conversion layer (corresponding to the photoelectric conversion layer of the invention) and a counter electrode layer (a transparent electrode layer, corresponding to the transparent conductive layer of the invention) which are provided on the substrate in this order, though the invention is not restricted thereto.

In the case where two organic layers are provided on a substrate, the photoelectric conversion layer stack is composed of, for example, a substrate and a pixel electrode layer (being a transparent electrode layer in many case), a photoelectric conversion layer, a counter electrode layer (a transparent electrode layer), an interlayer insulating layer, a pixel electrode layer (being a transparent electrode layer in many case), a photoelectric conversion layer and a counter electrode layer (a transparent electrode layer) which are provided on the substrate in this order.

As the material of the transparent electrode layer constituting the photoelectric conversion part, when it is not included in the scope of the transparent conductive layer of the invention having a sheet resistance of from 100 to 10000 Ω/□, use may be made of same kind of material as the material of the transparent conductive layer of the invention having a sheet resistance of from 100 to 10000Ω/□.

Particularly preferred examples of the material of the transparent electrode layer include ITO, IZO, SnO₂, ATO (antimony-doped tin oxide), ZnO, AZO (Al-doped zinc oxide), GZO (gallium-doped zinc oxide), TiO₂ and FTO (fluorine-doped tin oxide). The light transmittance of a transparent electrode layer at the photoelectric conversion light absorption peak wavelength of the photoelectric conversion layer contained in the photoelectric conversion element having the transparent electrode layer is preferably 60% or more, still preferably 80% or more, still preferably 90% or more and still preferably 95% or more. The preferable range of the surface resistance of the transparent electrode layer varies depending on, for example, whether being a pixel electrode or a counter electrode and whether the charge storage/transfer/reading part having a COD structure or a CMOS structure. In the case of using as a counter electrode and the charge storage/transfer/reading part having a CMOS structure, the surface resistance is preferably not more than 10000Ω/□, still preferably not more than 1000Ω/□. In the case of using as a counter electrode and the charge storage/transfer/reading part having a CCD structure, the surface resistance is preferably not more than 1000Ω/□, still preferably not more than 100Ω/□. In the case of using as a pixel electrode, the surface resistance is preferably not more than 1000000Ω/□, still preferably not more than 100000Ω/□.

Now, layer-forming conditions for the transparent electrode layer, when it is not included in the scope of the transparent conductive layer of the invention having a sheet resistance of from 100 to 10000Ω/□, will be described. In the layer-forming step of the transparent electrode layer, the substrate temperature is preferably 500° C. or below, still preferably 300° C. or below, still preferably 200° C. or below and still preferably 150° C. or below. A gas may be introduced during the transparent electrode layer formation. Although the gas is not fundamentally restricted in species, use may be made of Ar, He, oxygen, nitrogen or the like. It is also possible to use a mixture of these gases. In the case of using an oxide material, it is preferable to use oxygen since there frequently arises oxygen defect.

It is preferable to apply a voltage to the photoelectric conversion layer of the invention to improve the photoelectric conversion efficiency. Although the application voltage may be an arbitrary one, the required voltage level varies depending on the thickness of the photoelectric conversion layer. That is to say, a higher photoelectric conversion efficiency is obtained under the larger electric field applied to the photoelectric conversion layer. In the case of applying a definite voltage, the electric field is increased with a decrease in the thickness of the photoelectric conversion layer. In the case of using a thin photoelectric conversion layer, therefore, the applied voltage may be relatively low. The electric field to be applied to the photoelectric conversion layer is preferably 10 V/m or more, still preferably 1×10³ V/m or more, still preferably 1×10⁵ V/m or more, particularly preferably 1×10⁶ V/m or more and most desirably 1×10⁷ V/m or more. Although the upper limit thereof is not particularly specified, it is undesirable to apply an excessive electric field since a current flows even in a dark place in such a case. Thus, the electric field to be applied is preferably 1×10¹² V/, or less, still preferably 1×10⁹ V/m or less.

(Inorganic Layer)

Now, an inorganic layer serving as the electromagnetic wave absorption/photoelectric conversion part will be illustrated. In this case, light passing through the upper organic layer is photoelectrically converted in the inorganic layer. As the inorganic layer, use is generally made of a pn junction or a pin junction of semiconductor compounds such as crystalline silicone, amorphous silicone and GaAs. As a stacked structure, a method disclosed by U.S. Pat. No. 5,965,875 maybe employed. Namely, this method comprises forming a photo acceptance part stacked with the use of the wavelength-dependency of the absorption coefficient of silicone and performing color separation in the depth direction thereof. Since the color separation is carried out depending on the light transmission depth of silicone in this case, the spectra detected in individual acceptance parts stacked together have each a broad range. By using the organic layer as the upper layer as described above (i.e., detecting light transmitting the organic layer in the depth direction of silicone), however, the color separation can be remarkably improved. By providing a G layer as the organic layer, in particular, light transmitting through the organic layer is separated into B light and R light. As a result, the light may be divided merely into BR lights in the depth direction of silicone and thus the color separation is improved. In the case where the organic layer is a B layer or an R layer, the color separation can be remarkably improved too by appropriately selecting the electromagnetic wave absorption/photoelectric conversion part of silicone along the depth direction. In the case of forming two organic layers, the function as the electromagnetic wave absorption/photoelectric conversion part in silicone may be performed fundamentally in only one color and, in its turn, favorable color separation can be established.

In a preferable case, the inorganic layer has a structure wherein multiple photodiodes are stacked in the depth direction of a semiconductor substrate for individual pixels and color signals corresponding to the signal charges generating in the individual photodiodes due to light absorbed by the multiple photodiodes are read out. It is preferable that the multiple photodiodes involve at least one of a first photodiode located in the depth of absorbing B light and a second photodiode located in the depth of absorbing R light, and each of the photodiodes has a color signal reading circuit for reading a color signal corresponding to each of the signal charges. According to this constitution, color separation can be performed without resorting to a color filter. It is also possible in some cases to detect light in the negative component, which enables color image pickup with favorable color reproducibility. It is preferable in the invention that the joint part of the first photodiode is formed in a depth up to about 0.2 μm from the semiconductor substrate surface, while the joint of the second photodiode is formed in a depth up to about 2 μm from the semiconductor substrate surface.

Now, the inorganic layer will be illustrated in greater detail. Preferable examples of the inorganic layer constitution include photo acceptance elements of the photoconductive type, the p-n junction type, the shot-key junction type, the PIN junction type and the MSM (metal-semiconductor-metal) junction type and photo acceptance elements of the photo transistor type. It is preferable in the invention to employ a photo acceptance element wherein first conductive areas and second conductive areas being opposite to the first conductive areas are alternatively stacked on a single semiconductor substrate and the joint parts of the first conductive areas and the second conductive areas are formed respectively at depths appropriate mainly for the photoelectric conversion of a plural number of lights in different wavelength regions. As the single semiconductor substrate, monocrystalline silicone may be preferably employed. Thus, color separation can be performed by taking advantage of the absorption wavelength characteristics depending on the depth direction of the silicone substrate.

As the inorganic semiconductor, use can be made of InGaN-based, InAlN-based, In AlP-based or InGaAlP-based inorganic semiconductors. The InGaN-based inorganic semiconductor is prepared by appropriately altering the composition of In so as to achieve an absorption peak in the blue light wavelength region. That is to say, it is represented by InₓGa₁₋ₓN (0≦x<1). A semiconductor made of such a compound can be produced by the organic metal vapor phase epitaxy method (MOCVD method). An InAlN-based nitride semiconductor with the use of Al belonging to the same group (13) as Ga is also usable as a short wavelength light acceptor part as in the InGaN-based one. Furthermore, use can be also made of InAlP and InGaAlP lattice-matching a GaAs substrate.

The inorganic semiconductor may have an embedded structure. The term “embedded structure” means a constitution wherein both ends of a short wavelength light acceptor part are covered with a semiconductor which is different from the short wavelength light acceptor part. As the semiconductor covering both ends, it is preferable to employ a semiconductor having a band gap wavelength which is shorter than the band gap wavelength of the short wavelength light acceptor part or equals thereto.

The organic layer and the inorganic layer may be bonded in an arbitrary manner. It is preferable to provide an insulating layer between the organic layer and the inorganic layer to thereby electrically insulating them.

An npn-junction or a pnpn-junction, from the incident light side, is preferred. The pnpn-junction is still preferred, since the surface potential can be maintained at a high level by forming a p layer on the surface and thus holes and a dark current generating on the surface can be trapped, thereby lowering the dark current.

In such a photodiode, an n-type layer, a p-type layer, an n-type layer and a p-type layer are deeply formed in this order, i.e., being successively diffused from the p-type silicone substrate surface, and thus a pn-junction diode is formed in the depth direction of the silicone to give four layers (pnpn). Incident light with a longer wavelength entering from the diode surface side the more deeply transmits and the incident wavelength and the attenuation coefficient are inherent to silicone. Thus, the diode is designed so that the pn junction face covers the wavelength region of visible light. Similarly, an n-type layer, a p-type layer and an n-type layer are formed in this order to give a junction diode having three layers (npn). A light signal is taken out from the n-type layer, while the p-type layer is ground connected.

By forming a drawing electrode in each area and applying a definite reset potential thereto, each area becomes depletion and the capacity in each junction part is highly lessened. Thus, the capacity generating in the junction face can be highly lessened.

(Auxiliary Layer)

It is preferable in the invention to provide an ultraviolet absorption layer and/or an infrared absorption layer as the uppermost layer of the electromagnetic wave absorption/photoelectric conversion part. The ultraviolet absorption layer can absorb or reflect light having wavelength of at least 400 nm or less and it preferably has an absorption index in a wavelength region of 400 nm or less of 50% or more. The infrared absorption layer can absorb or reflect light having wavelength of at least 700 nm or more and it preferably has an absorption index in a wavelength region of 700 nm or more of 50% or more.

These ultraviolet absorption layer and infrared absorption layer can be formed by publicly known methods. For example, there has been known a method which comprises forming a mordant layer made of a hydrophilic polymer such as gelatin, casein, glue or polyvinyl alcohol on the substrate and adding a dye having a desired absorption wavelength to the mordant layer or dyeing the mordant layer to form a color layer. Another known method comprises using a colored resin wherein a specific coloring matter is dispersed in a transparent resin. Moreover, use may be made of a colored resin layer comprising a mixture of a polyamino resin with a coloring matter, as reported by JP-A-58-46325, JP-A-60-78401, JP-A-60-184202, JP-A-60-184203, JP-A-60-184204, JP-A-60-184205 and so on. It is also possible to use a coloring agent comprising a photosensitive polyimide resin.

Furthermore, it is possible to disperse a coloring matter in an aromatic polyamide resin which has a photosensitive group in its molecule and can provide a hardened layer at 200° C. or below, as reported by JP-B-7-113685. Also, use can be made of a dispersion colored resin in an amount as specified in JP-B-7-69486.

In the invention, it is preferable to use a dielectric multiple layer. The advantage of using a dielectric multiple layer resides in that it has a sharp wavelength-dependency of light transmission.

It is preferable that individual electromagnetic wave absorption/photoelectric conversion parts are separated by insulating layers. These insulating layers can be formed by using transparent insulating materials such as glass, polyethylene, polyethylene terephthalate, polyether sulfone or polypropylene. Also, use may be preferably made of silicon nitride, silicon oxide and the like. A silicon nitride layer formed by the plasma CVD method is preferably used because of being highly dense and highly transparent.

To prevent direct contact with oxygen or moisture, it is also possible to form a protective layer or a blocking layer. Examples of the protective layer include a diamond layer, layers made of inorganic materials such as metal oxides and metal nitrides, layers made of polymers such as fluororesins, poly(para-xylene), polyethylene, silicone resins and polystyrene resins, and photosetting resins. It is also possible package the element per se by covering it with glass, a gas non-permeable plastic, a metal, etc. In this case, it is also possible to enclose a substance having a high water absorption property in the package.

Furthermore, it is preferable to employ an embodiment wherein a microlens array is formed in the upper part of the photo acceptance element so as to improve the light collection efficiency.

(Charge Storage/Transfer/Reading Part)

Concerning the charge storage/transfer/reading part, reference may be made to JP-A-58-103166, JP-A-58-103165, JP-A-2003-332551 and so on. Namely, use may be appropriately made of a constitution wherein MOS transistors are formed for individual pixels on a semiconductor substrate or a constitution having CCD as an element. In the case of a photoelectric conversion element with the use of MOS transistors, for example, electric charge arises in a photoconductive layer due to incident light transmitting through electrodes. By applying a voltage to the electrodes, an electric field is formed between the electrodes and thus the charge migrates across the photoconductive layer toward the electrodes. Then the charge enters into a charge storage part in the MOS transistor and stored therein. The charge stored in the charge storage part transfers to a charge-reading part by switching the MOS transistor and then output as an electric signal. Owing to this mechanism, a full color image signals are input in the solid-state image pickup device having a signal processing part.

It is also possible that a definite amount of bias charge is injected into a storage diode (a refresh mode) and, after storing a definite charge (a photoelectric conversion mode), the signal charge is read out. It is possible to use a photo acceptance element per se as a storage diode or to separately provide a storage diode.

Next, signal reading will be illustrated in greater detail. Signals can be read by using a conventional color reading circuit. A signal charge or a signal current phtoelectrically converted in the photo acceptance part is stored in the photo acceptance part per se or a capacitor provided separately. The thus stored charge is read simultaneously with the selection of pixel position by the means of MOS image pickup element with the use of the X-Y address system (a so-called CMOS sensor). As another reading method, an address selection system which comprises successively selecting pixels one by one with a multi prexar switch and a digital shift switch and reading as a signal voltage (or charge) along a common output curve may be cited. There is an image pickup element with the use of a two-dimensionally arrayed X-Y address operation which is known as a CMOS sensor. In this element, a switch attached to the X-Y intersection is connected to a perpendicular shift resistor. When the switch is turned on by the voltage from the perpendicular scanning shift resistor, signals read from pixels in the same line are read along the output curve in the ray direction. These signals are read one by one from the output end through a switching mechanism which is driven by a horizontal scanning shift resistor.

To read output signals, use can be made of a floating diffusion detector or a floating gate detector. Moreover, S/N can be improved by providing pixels with a signal amplification circuit or using the correlated double sampling method.

Signals can be processed by using gamma correlation with the use of an ADC circuit, digitalization with the use of an AD converter, the luminance signal processing method or the color signal processing method. Examples of the color signal processing method include white balance processing, color separation processing, color matrix processing and so on. In order to use as NTSC signals, the RGB signals can be converted into YIQ signals.

In the charge transfer/reading part, the charge migration rate should be 100 cm²/volt sec or higher. Such a migration rate can be established by selecting an appropriate semiconductor material belonging to the group IV, III-V or II-VI. Among all, it is preferable to employ silicone semiconductors (also called Si semiconductors), since fine processing techniques have advanced in this field and they are available at low cost. There have been proposed a large number of charge transfer/charge reading systems and any of these systems is usable. A CMOS-type or CCD-type device system is particularly preferred. In the invention, the CMOS-type system is preferred in various points including high-speed reading, pixel integration, partial reading and power consumption.

(Connection)

Multiple parts for connecting the electromagnetic wave absorption/photoelectric conversion part to the charge storage/transfer/reading part may be made of any metal. It is preferable to use a metal selected from among copper, aluminum, silver, gold, chromium and tungsten and copper is particularly preferable therefor. Contact parts should be respectively provided between individual electromagnetic wave absorption/photoelectric conversion parts and individual charge storage/transfer/reading parts. In the case of using a stacked structure comprising blue, green and red light photosensitive units, it is necessary to connect a fetch electrode for blue light to a charge transfer/reading part, to connect a fetch electrode for green light to a charge transfer/reading part and to connect a fetch electrode for red light to a charge transfer/reading part respectively.

(Process)

The stacked photoelectric conversion element according to the invention can be fabricated in accordance with a so-called micro fabrication process employed in producing publicly known integrated circuits and so on. In this process, the following procedures are repeated fundamentally: pattern exposure with the use of active rays or electron beams (i, g bright-line of mercury, eximer laser, X-ray, electron beams, etc.); pattern formation by development and/or burning; provision of element-forming materials (coating, vapor deposition, sputtering, CV, etc.); and removal of the materials from non-pattern areas (heating, dissolution, etc.).

(Use)

Concerning the chip size, the device may have the brownie size, the 135 size, the APS size, the 1/1.8 size or a smaller size. In the stacked photoelectric conversion element of the invention, the pixel size is expressed in diameter of a circle corresponding to the maximum area of multiple electromagnetic wave absorption/photoelectric conversion parts. Although any pixel size may be used, a pixel size of 2 to 20 μm is preferable, still preferably 2 to 10 μm and particularly preferably 3 to 8 μm.

In the case where the pixel size exceeds 20 μm, the resolution is lowered. In the case where the pixel size is less than 2 μm, the resolution is also lowered due to radio interference among sizes.

The photoelectric conversion element of the invention is usable in digital still cameras. It is also preferably usable in TV cameras. In addition thereto, the photoelectric conversion element of the invention is usable in digital video cameras, monitor cameras (to be used in, for example, office buildings, parking areas, financial institutions, automatic loan-application machines, shopping centers, convenience stores, outlet malls, department stores, pinball parlors, karaoke boxes, game centers and hospitals), other various sensors (entrance monitors, identification sensors, sensors for factory automation, robots for household use, robots for industrial use and pipe inspection systems), medical sensors (endoscopes and fundus cameras), TV conference systems, TV telephones, camera-equipped cell phones, safe driving systems for automobiles (back guide monitors, collision-estimating systems and lane-keeping systems), sensors for TV games and so on.

Among all, the photoelectric conversion element of the invention is appropriately usable in TV cameras. This is because the photoelectric conversion element of the invention requires no optical system for color separation and thus contributes to the reduction in size and weight of TV cameras. Moreover, it has a high sensitivity and a high resolution and, therefore, is particularly preferable in TV cameras for high-definition broadcast. The TV cameras for high-definition broadcast as used herein include cameras for digital high-definition broadcast.

The photoelectric conversion element of the invention requires no optical low pass filter, which makes it further preferable from the viewpoint of achieving an increased sensitivity and improved resolution.

Furthermore, the thickness of the photoelectric conversion element according to the invention can be lessened and no optical system for color separation is required therein. Thus, it can provide a single camera which meets various photography-related needs. Namely, scenes wherein different sensitivities are needed, e.g., “environments with a change in brightness, e.g., daytime and night”, “a still subject and a moving subject” and so on, and scenes wherein different spectral sensitivities or color reproductions are needed can be taken with the use of a single camera merely replacing the photoelectric conversion elements of the invention. Therefore, it becomes unnecessary to carry a plural number of cameras, which lessen the load on a photographer. To replace the photoelectric conversion elements, the above-described photoelectric conversion element is prepared together with spare photoelectric conversion elements for, e.g., infrared light photographing, monochromic photographing, dynamic range replacement and so on.

The TV camera according to the invention can be fabricated by reference to Terebi camera no Sekkei Gijutsu, ed. by The Institute of Image Information and Television Engineers (Aug. 20, 1988, Corona, ISBN 4-339-00714-5) chap. 2 and replacing, for example, the optical system for color separation and the image pickup device in Fig. 2.1 (Fundamental Constitution of TV Camera) therein by the photoelectric conversion element of the invention.

The stacked photo acceptance elements as described above may be used as an image pickup element by aligning. Alternatively, a single device can be used as a photo sensor or a color photo acceptance element in biosensors and chemical sensors.

(Preferable Photoelectric Conversion Element According to the Invention)

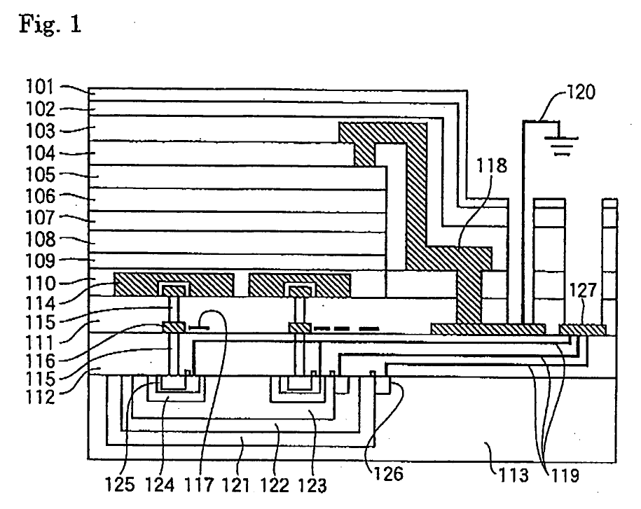

Next, a preferable photoelectric conversion element of the invention will be illustrated by referring to FIG. 1. In FIG. 1, 113 is a monocrystalline silicone base which also serves as electromagnetic wave absorption/photoelectric conversion parts for B light and R light and a charge storage/transfer/reading part for the charge generated by photoelectric conversion, A p-type silicone substrate is usually employed therefor. 121, 122 and 123 respectively show an n layer, a player and another n layer formed in the silicone base. The n layer 121 is an R light signal charge storage part in which R light signal charge photoelectrically converted by the pn junction is stored. The thus stored charge is connected to a signal reading pad 127 by a metal wiring 119 via a transistor 126. The n layer 123 is a B light signal charge storage part in which B light signal charge photoelectrically converted by the pn junction is stored. The thus stored charge is connected to the signal reading pad 127 by the metal wiring 119 via a transistor similar to the transistor 126. Although the p layer, n layers, transistors, metal wirings, etc. are schematically indicated therein, each member has an appropriately selected structure, etc. as discussed above. Since B light and R light are fractionated depending on silicone base depth, it is important to appropriately select the depth of the pn junction etc. from the silicone base, the dope concentration and so on. A layer 112 contains a metal wiring and comprises silicon oxide, silicone nitride, etc. as the main component. A less thickness of the layer 112 is preferred. Namely, its thickness is 5 μm or less, preferably 3 μm or less and still preferably 2 μm or less. Similarly, a layer 111 comprises silicon oxide, silicone nitride, etc. as the main component. Between the layers 111 and 112, a plug for transferring G light signal charge to the silicone base is provided. The plug is connected by a pad 116 between the layers 111 and 112. As the plug, use is preferably made of one comprising tungsten as the main component. It is preferred that a barrier layer is formed including the metal wiring as described above. The G light signal charge transferred through the plug 115 is stored in the n layer 125 in the silicone base. The n layer 125 is separated by the p layer 124. The stored charge is connected to the signal reading pad 127 by the metal wiring 119 via a transistor similar to the transistor 126. Since the photoelectric conversion by the pn junction of 124 and 125 brings about noises, a photo blocking layer 117 is provided in the layer 111. As the photo blocking layer, use is usually made of one comprising tungsten, aluminum or the like as the main component. A less thickness of the layer 112 is preferred. Namely, its thickness is 3 μm or less, preferably 2 μm or less and still preferably 1 μm or less. It is preferable to provide a signal reading pad 127 for each of B, G and R signals. The above described process can be carried out by a publicly known process, i.e., the so-called CMOS process.

The electromagnetic wave absorption/photoelectric conversion parts of G light are represented by 105, 106, 107, 108, 109, 110 and 114. The electromagnetic wave absorption/photoelectric conversion parts 105 and 114 are transparent electrodes which correspond respectively to a counter electrode and a pixel electrode. Although the pixel electrode 114 is a transparent electrode, it is frequently needed to provide a part made of aluminum, molybdenum, etc. to the connection area so as to achieve favorable electrical connection to a plug 115. A bias is loaded on these transparent electrodes via the wirings from a connection electrode 118 and the counter electrode pad 120. In a preferred structure, positive bias is loaded on the pixel electrode 114 to the counter electrode 105 and thus electrons are stored in 125. In this case, 107 serves as an electron blocking layer, 108 serves as a p layer, 109 serves as an n layer and 110 serves as a hole blocking layer, thus showing a typical layer structure of the organic layers. 106 is a buffer layer. The total thickness of the organic layers 107, 108, 109 and 110 is preferably 0.5 μm or less, still preferably 0.3 μm or less and particularly preferably 0.2 μm or less. The thicknesses of the transparent counter electrode 105 and the transparent pixel electrode 114 are preferably 0.2 μm or less. 103 and 104 are protective layers comprising silicon nitride, etc. as the main component. Owing to these protective layers, the process for producing the layers including the organic layers becomes easy. These layers particularly contribute to the relief in damages on the organic layers in the course of the resist pattern formation, etching, etc. in constructing the connection electrodes such as 118. It is also possible to employ a fabrication process with the use of a mask to omit the steps of forming a resist pattern and etching. The thicknesses of the protective layers 103 and 104 are preferably 0.5 μm or less, so long as the above-described requirements are fulfilled.

103 is a protective layer of the connection electrode 118. 102 is a stack composed of an infrared-cutting dielectric multiple layer and an ultraviolet-cutting layer. 101 is an antireflective layer. It is preferable that the total thickness of the layers 101, 102 and 103 is 1 μm or less.

In the photoelectric conversion element shown in FIG. 1 as described above, four G pixels are employed per B pixel and R pixel. One G pixel maybe used per B pixel and R pixel. Three G pixels may be used per B pixel and R pixel. Two G pixels may be used per B pixel and R pixel. Moreover, other arbitrary combinations may be employed. Although a preferred embodiment of the invention has been described above, the invention is not restricted thereto.

### EXAMPLES

Next, an example of the invention will be provided. However, it is needless to say that the invention is not restricted thereto.

### Example 1

In the preferable photoelectric conversion element structure as discussed above, an MgAg layer of 10 nm in thickness was formed as a buffer layer 106. A pixel transparent electrode 114 was formed by using ITO and its layer thickness was 50 nm. The sheet resistance of the pixel transparent electrode 114 was 200Ω/□. In the case of the invention, a transparent electrode 105 was formed by the rf sputtering method (TS distance: 10 cm) wherein the O₂ inlet amount corresponded to 4% of the total gas inlet amount and the layer-forming temperature was 25° C. In Comparative Example, on the other hand, a transparent electrode 105 was formed by introducing 0.5% of O₂ based on the total gas inlet amount and the layer-forming temperature was 25° C. As substitutes for the organic layers 107 to 110 in the preferred photoelectric conversion element, a tris-8-hydroxyquinoline aluminum (Alq) layer (50 nm) and a 2,9-dimethylquinacridone layer were formed from the substrate side by the heat deposition method.

As the results of the measurement of sheet resistances and transmittances of the transparent electrodes thus obtained, the sheet resistance of the invention sample was 800Ω/□ while that of the comparative sample was 80Ω/□. The transmittance of the invention sample at the wavelength of 550 nm was 85% or higher, while that of the comparative sample was 80% or higher.

The dark current value of the invention sample was 0.5 by referring that of the comparative sample as to 1 and these samples were equivalent in sensitivity. Thus, an element with an improved S/N ratio could be fabricated according to the invention.

### Example 2

In the preferable photoelectric conversion element structure as described above, a transparent electrode 105 was formed by the rf sputtering method (TS distance: 10 cm) wherein the O₂ inlet amount corresponded to 0% of the total gas inlet amount and the layer-forming temperature was 25° C. to give a layer 10 nm in thickness. In Comparative Example, on the other hand, a transparent electrode 105 was formed by introducing 0.5% of O₂ and the layer-forming temperature was 25° C. to give a layer of 100 nm in thickness. As substitutes for the organic layers 106 to 110 in the preferred photoelectric conversion element, a tris-8-hydroxyquinoline aluminum (Alq) layer (50 nm) and a 2,9-dimethylquinacridone layer (100 nm) were formed from the substrate side by the heat deposition method.

As the results of the measurement of sheet resistances and transmittances of the transparent electrodes thus obtained, the sheet resistance of the invention sample was 1500Ω/□ while that of the comparative sample was 80Ω/□. The transmittance of the invention sample at the wavelength of 550 nm was 95% or higher, while that of the comparative sample was 80% or higher.

Upon the application of negative voltage (1V) to the transparent electrode 105 side, the dark current value of the invention sample was 0.001 by referring that of the comparative sample as to 1.

Thus, an element with an improved S/N ratio could be fabricated according to the invention.

The image pickup element of the invention is applicable to image pickup elements typified by digital cameras, video cameras, facsimiles, scanners, copy machines and so on. Moreover ,it is usable as a light sensor in biosensors, chemical sensors and so on.

This application is based on Japanese Patent application JP 2005-53006, filed Feb. 28, 2005, the entire content of which is hereby incorporated by reference, the same as if set forth at length.

What is claimed is:

1. A photoelectric conversion element comprising: a substrate; a conductive layer; a photoelectric conversion layer; and a transparent conductive layer, provided in this order, wherein the transparent conductive layer has a sheet resistance of from 100 to 10000Ω/□.

2. The photoelectric conversion element as claimed in claim 1, wherein the sheet resistance is from 100 to 3000Ω/□.

3. The photoelectric conversion element as claimed in claim 1, wherein the sheet resistance is from 500 to 1000Ω/□.

4. The photoelectric conversion element as claimed in claim 1, wherein a transmittance in an incidence wavelength region of from 400 to 700 nm is 85% or more.

5. The photoelectric conversion element as claimed in claim 2, wherein a transmittance in an incidence wavelength region of from 400 to 700 nm is 85% or more.

6. The photoelectric conversion element as claimed in claim 3, wherein a transmittance in an incidence wavelength region of from 400 to 700 nm is 85% or more.

7. The photoelectric conversion element as claimed in claim 1, wherein a transmittance in an incidence wavelength region of from 400 to 700 nm is 90% or more.

8. The photoelectric conversion element as claimed in claim 2, wherein a transmittance in an incidence wavelength region of from 400 to 700 nm is 90% or more.

9. The photoelectric conversion element as claimed in claim 3, wherein a transmittance in an incidence wavelength region of from 400 to 700 nm is 90% or more.

10. The photoelectric conversion element as claimed in claim 1, wherein the transparent conductive layer contains a conductive metal oxide.

11. The photoelectric conversion element as claimed in claim 1, wherein the transparent conductive layer contains In₂O₃-based material or ZnO-based material.

12. The photoelectric conversion element as claimed in claim 1, wherein the transparent conductive layer contains indium tin oxide or indium zinc oxide.

13. A method for producing a photoelectric conversion element as claimed in claim 1, wherein the transparent conductive layer is formed by a plasma-free layer-formation method.
